(19) United States
(12) Patent Application Publication
(10) Pub. No.: US 2014/0177187 A1
(43) Pub. Date: Jun. 26, 2014

(54) MOUNTING APPARATUS FOR EXPANSION CARD

(71) Applicants: HON HAI PRECISION INDUSTRY CO., LTD., New Taipei (TW); HONG FU JIN PRECISION INDUSTRY (SHENZHEN) CO., LTD., Shenzhen (CN)

(72) Inventors: YU-WEI HE, Shenzhen (CN); XIU-QUAN HU, Shenzhen (CN)

(73) Assignees: HON HAI PRECISION INDUSTRY CO., LTD., New Taipei (TW); HONG FU JIN PRECISION INDUSTRY (SHENZHEN) CO., LTD., Shenzhen (CN)

(21) Appl. No.: 13/962,912

(22) Filed: Aug. 8, 2013

(30) Foreign Application Priority Data
Dec. 21, 2012 (CN) 2012105593659

(51) Int. Cl. H05K 7/14

(52) U.S. Cl. CPC H05K 7/1417
USPC 361/759

(57) ABSTRACT

A mounting apparatus includes an enclosure, a securing member, a positioning member, and a latching member. The securing member is configured to be secured to a first end of an expansion card and engaged with the enclosure for preventing the expansion card from moving along a first direction. The positioning member is configured to be secured to a second end of an expansion card and secured to the enclosure for preventing the expansion card from moving along a second direction opposite to the first direction. The latching member is installed on the enclosure. The latching member is engaged with the positioning member so that prevent the expansion card from moving along a third direction perpendicular to the first direction and the second direction.

### BACKGROUND

1. Technical Field

The present disclosure relates to mounting apparatuses, and more particularly to a mounting apparatus for securing an expansion card in an enclosure.

2. Description of Related Art

A computer system usually includes a plurality of expansion cards, such as sound cards, video cards, and graphics cards, for enhancing capabilities of the computer system. Generally, a first end of the expansion card is inserted into a securing slot of a circuit board, a second end of the expansion card is free, so that when the computer system suffers shock, the second end of the expansion card may swing to disengage the expansion card from the securing slot. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a mounting apparatus and an expansion card.

FIG. 2 is an isometric view of a pressing member of FIG. 1.

FIG. 3 is an isometric view of a positioning member of FIG. 1.

FIG. 4 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

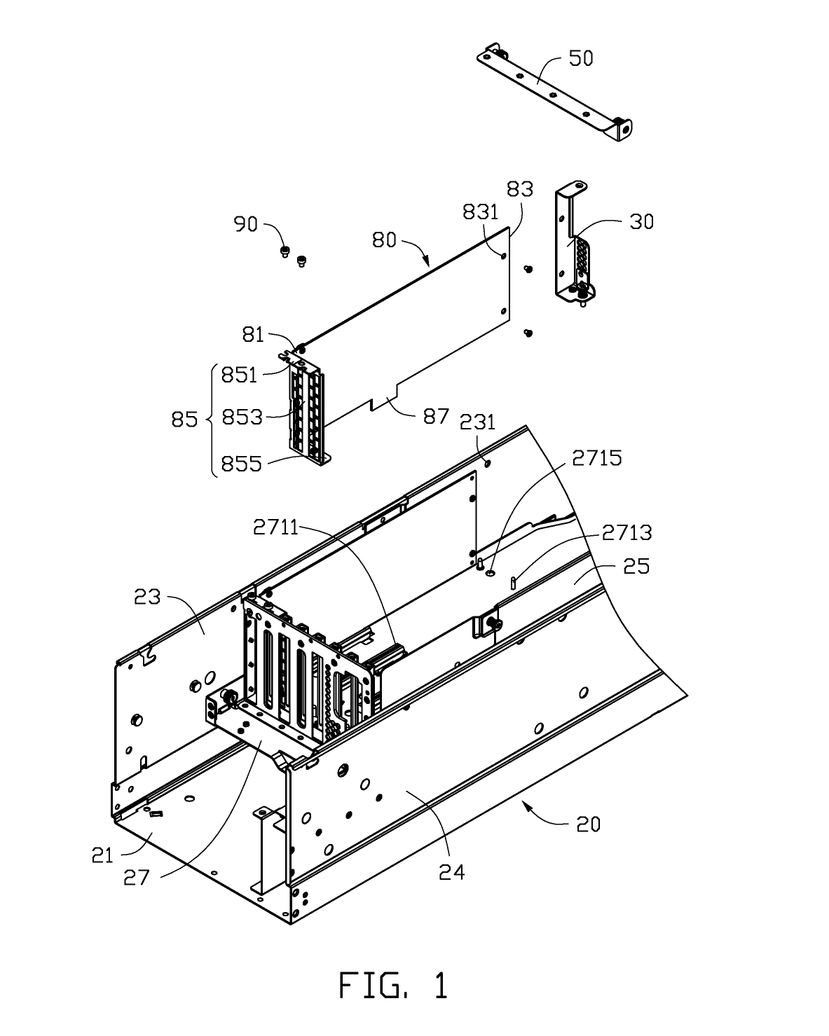

FIG. 1 shows a mounting apparatus of the embodiment. The mounting apparatus is configured for mounting an expansion card 80. The mounting apparatus includes an enclosure 20, a positioning member 30, a latching member 50, and a securing member 85.

The enclosure 20 includes a bottom plate 21, a first sidewall 23, a second sidewall 24, and a separated plate 25. The first sidewall 23 and the second sidewall 24 are located on opposite sides of the bottom plate 21. The separated plate 25 extends upwards from the bottom plate 21 and is located between the first sidewall 23 and the second sidewall 24. In one embodiment, the first sidewall 23 and the second sidewall 24 are parallel to each other and perpendicular to the bottom plate 21, and the separated plate 25 is parallel to the first sidewall 23 and the second sidewall 24 and perpendicular to the bottom plate 21. A bearing tray 27 is installed between the first sidewall 23 and the separated plate 25, for supporting the expansion card 80. A locking hole 231 is defined in both the separated plate 25 and the first sidewall 23, corresponding to the latching member 50. A circuit board 271 is installed on the bearing tray 27 and defines a securing slot 2711 corresponding to the expansion card 80. A positioning post 2713 protrudes from the bearing tray 27. A securing hole 2715 is defined in the bearing tray 27 adjacent to the positioning post 2713 corresponding to the positioning member 30. A supporting bracket 29 is secured to the bearing tray 27 and arranged at one side of the securing slot 2711 for engaging with the securing member 85.

The expansion card 80 includes a first end 81 and a second end 83 opposite to the first end 81. The securing member 85 is secured to the first end 81 and includes a latching tab 851, an abutting piece 855, and a connecting piece 853. The connecting piece 853 is connected to the latching tab 851 and the abutting piece 855. An inserting tab 87 extends from a bottom edge of the expansion card 80 for engaging in the securing slot 2711. The second end 83 defines two installation holes 831 for securing the positioning member 30.

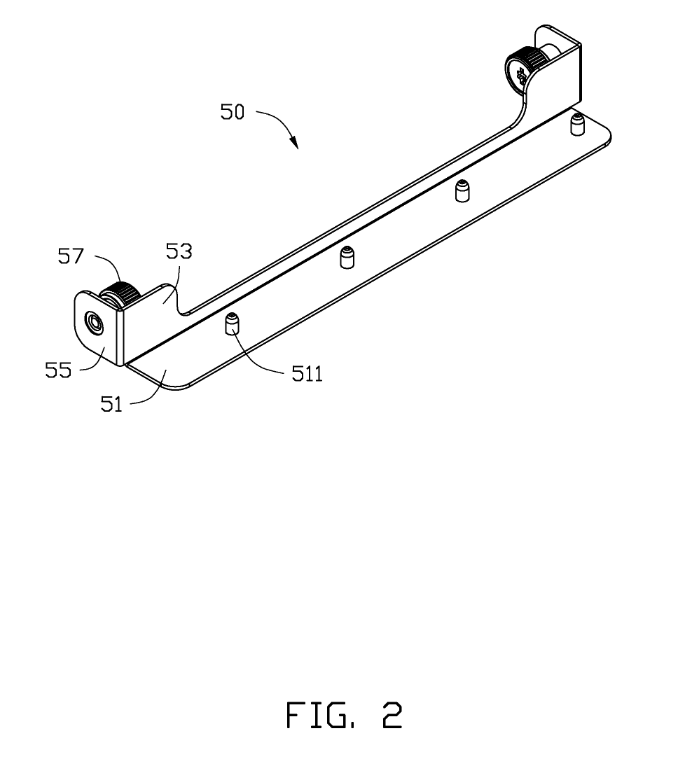

FIG. 2 shows that, the positioning member 30 includes a positioning tab 31, a securing plate 33, and a resisting tab 35. The positioning tab 31 and the resisting tab 35 perpendicularly extend from opposite ends of the securing plate 33. The positioning tab 31 defines a through hole 311 for receiving the positioning post 2713, and a locking portion 313 is installed on the positioning tab 31 adjacent to the through hole 311. The securing plate 33 defines two engaging holes 331 corresponding to the two installation holes 831. A stopping flange 333 extends from an edge of the securing plate 33 to block the expansion card 80. The resisting tab 35 defines a resisting hole 351 corresponding to the latching member 50.

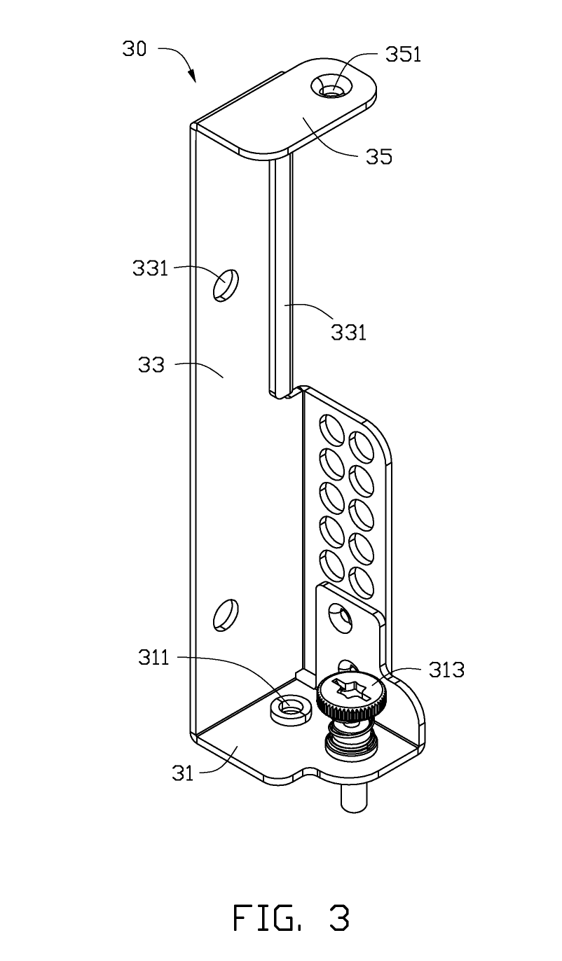

FIG. 3 shows that the latching member 50 includes an elongated pressing piece 51 and a converting piece 53. The pressing piece 51 is perpendicular to the converting piece 53 and the expansion card. A latching post 511 protrudes from the pressing piece 51. Two locking tabs 55 extend from two opposite ends of the converting piece 53. Two locking members 57 are installed on the two locking tabs 55. The two locking tabs 55 are parallel to each other and parallel to the first sidewall 23 and separated plate 25.

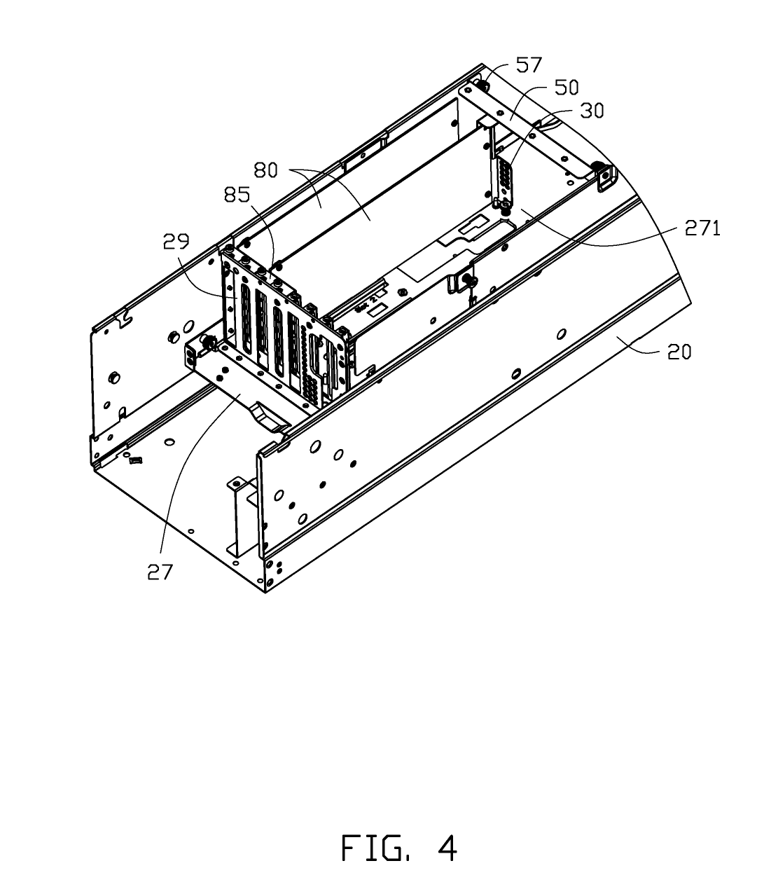

FIG. 4 shows that in assembly, the positioning member 30 is secured to the second end 83 by two screws locking into the two engaging holes 331 and the installation holes 831. The second end 83 abuts the stopping flange 333.

The insertion tab 87 of the expansion card 80 is inserted into the securing slot 2711 of the enclosure 20. The latching tab 851 is engaged with the supporting bracket 29 and two screws 90 are locked into the latching tab 851 and the supporting bracket 29, for preventing the expansion card 80 from moving in a first direction parallel to the first sidewall 23. The positioning post 2713 is engaged in the through hole 311 of the positioning member 30. The locking portion 313 is aligned with the securing hole 2715 and locked into the securing hole 2715, preventing the expansion card 80 from moving along a second direction opposite to the first direction.

The latching post 511 of the latching member 50 is received in the resisting hole 351, and the pressing piece 51 abuts the resisting tab 35. The two locking tabs 55 abut the first sidewall 23 and the separated plate 25, respectively. Each of the two locking members 57 is locked into the locking hole 231 of the first sidewall 23 and the separated plate 25. The latching member 50 is thereby secured to the enclosure 20, and the pressing piece 51 abuts the positioning member 30 to prevent the expansion card from disengaging from the securing slot 2711 along a third direction, that is perpendicular to the first direction and the second direction.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. A mounting apparatus comprising:
an enclosure;
a securing member configured to secure a first end of an expansion card to the enclosure for preventing the expansion card from moving along a first direction;
a positioning member configured to secure a second end of the expansion card to the enclosure, for preventing the expansion card from moving along a second direction which is opposite to the first direction; and
a latching member installed on the enclosure, the latching member being engaged with the positioning member, for preventing the expansion card from moving along a third direction which is perpendicular to the first direction and the second direction.

2. The mounting apparatus of claim 1, wherein the enclosure comprises a bearing tray, a positioning post is located on the bearing tray, the positioning member comprises a positioning tab defining a through hole; and the positioning post is received in the through hole to position the positioning member on the bearing tray.

3. The mounting apparatus of claim 2, wherein the positioning member further comprises a resisting tab defining a resisting hole; the latching member comprises a pressing piece, a latching post protrudes from the pressing piece, and the latching post is engaged in the resisting hole; and the pressing piece abuts the resisting tab.

4. The mounting apparatus of claim 3, wherein the positioning member further comprises a securing plate to secure the second end of the expansion card, and the securing plate is connected to the positioning tab and the resisting tab.

5. The mounting apparatus of claim 4, wherein the resisting tab and the positioning tab are parallel to each other and perpendicular to the securing plate.

6. The mounting apparatus of claim 2, wherein a latching portion is installed on the positioning tab, and the bearing tray further defines a securing hole; and the latching portion is locked into the securing hole, to secure the positioning member to the bearing tray.

7. The mounting apparatus of claim 3, wherein the latching member further comprises a converting piece connected to the pressing piece; and the converting piece is secured to the enclosure.

8. The mounting apparatus of claim 7, wherein the enclosure further comprises a first sidewall and a separated plate opposite to the first sidewall, two locking tabs extend from opposite ends of the converting piece, and each of the two locking tabs is secured to each of the first sidewall and the separated plate.

9. The mounting apparatus of claim 7, wherein the converting piece is perpendicular to the pressing piece.

10. A mounting apparatus comprising:
an enclosure comprising a circuit board, and the circuit board defining a latching slot configured to receive an expansion card;
a securing member;
a positioning member; and
a latching member installed on the enclosure,
wherein the securing member and the positioning member are configured to secure the expansion card to the enclosure, for preventing the expansion card from moving in a plane that is parallel to the circuit board; and the latching member is engaged with the positioning member for preventing the expansion card from moving along a direction which is perpendicular to the plane.

11. The mounting apparatus of claim 10, wherein the securing member is configured to secure a first end of the expansion card to the enclosure; and the positioning member is configured to secure a second end opposite to the expansion card to the enclosure.

12. The mounting apparatus of claim 11, wherein the enclosure comprises a bearing tray, a positioning post is located on the bearing tray; the positioning member comprises a positioning tab defining a through hole; and the positioning post is received in the through hole to position the positioning member on the bearing tray.

13. The mounting apparatus of claim 12, wherein the positioning member further comprises a resisting tab defining a resisting hole; the latching member comprises a pressing piece, and a latching post protrudes from the pressing piece; and the latching post is engaged in the resisting hole, and the pressing piece abuts the resisting tab.

14. The mounting apparatus of claim 13, wherein the positioning member further comprises a securing plate secured to the second end of the expansion card; and the securing plate is connected to the positioning tab and the resisting tab.

15. The mounting apparatus of claim 14, wherein the resisting tab and the positioning tab are parallel to each other and perpendicular to the securing plate.

16. The mounting apparatus of claim 12, wherein a latching portion is installed on the positioning tab, the bearing tray defines a securing hole; and the latching portion is locked into the securing hole, to secure the positioning member to the bearing tray.

17. The mounting apparatus of claim 13, wherein the latching member further comprises a converting piece connected to the pressing piece; and the converting piece is secured to the enclosure.

18. The mounting apparatus of claim 17, wherein the enclosure further comprises a first sidewall and a separated plate opposite to the first sidewall; two locking tabs extend from opposite ends of the converting piece; and each of the two locking tabs is secured to each of the first sidewall and the separated plate.

19. The mounting apparatus of claim 17, wherein the converting piece is perpendicular to the pressing piece.
